(19) United States
(12) Patent Application Publication
(10) Pub. No.: US 2009/0022886 A1
(43) Pub. Date: Jan. 22, 2009

(54) METHOD FOR MAKING AN INTERACTIVE INFORMATION DEVICE AND PRODUCT PRODUCED THEREBY

(75) Inventors: Eugene Halsey, IV, Holland, MI (US); Catherine A. Getz, Holland, MI (US)

Correspondence Address: VAN DYKE, GARDNER, LINN & BURKHART, LLP, SUITE 207, 2851 CHARLEVOIX DRIVE, S.E., GRAND RAPIDS, MI, 49546, US

(73) Assignee: DONNELLY CORPORATION, Holland, MI (US)

(21) Appl. No.: 12/200,159

(22) Filed: Aug. 28, 2008

Related U.S. Application Data
(62) Division of application No. 10/744,522, filed on Dec. 23, 2003.
Application No. 10/744,522 is a division of application No. 09/974,209, filed on Oct. 10, 2001, now abandoned.
(60) Provisional application No. 60/239,788, filed on Oct. 12, 2000.

(51) Int. Cl. B05D 5/12; G03F 7/20; C23C 14/34; G06F 3/042

(52) U.S. Cl. 427/109; 430/322; 204/192.1; 345/175

(57) ABSTRACT

A method and product produced by the method for forming an interactive information device with a conductively coated panel includes forming a reduced contrast, increased light transmitting, conductively coated panel by providing a transparent substrate and applying a transparent, conductive layer on at least one surface of the substrate in a predetermined pattern with at least one area having a conductive layer thereon and a second area without a conductive layer. The method further includes applying a transparent layer of a metal oxide such that the metal oxide layer, such as silicon dioxide, overlies both areas whereby visible contrast between the areas is reduced and light transmission through the coated panel is increased. The coated panel is then attached to an electro-optic display for displaying information when electricity is applied thereto.

### CROSS REFERENCE TO RELATED APPLICATION

This application is a division of U.S. patent application Ser. No. 10/744,522, filed Dec. 23, 2003, which is a division of U.S. patent application Ser. No. 09/974,209, filed Oct. 10, 2001, now abandoned, which claims priority from U.S. Provisional Patent Application Ser. No. 60/239,788, filed Oct. 12, 2000, the disclosures of which are hereby incorporated by reference herein.

### TECHNICAL FIELD AND BACKGROUND OF THE INVENTION

This invention relates to an improved conductively coated transparent substrate as used in an interactive touch information display such as a transparent digitizer, near field imaging touch screen, electromagnetic touch screen, or an electrostatic touch screen. These products typically utilize a transparent conductive thin film on a rigid glass substrate and with the transparent conductor deposited in a specific pattern as required by product design and with a region coated with a transparent conductor immediately adjacent to a region uncoated with a transparent conductor. This results in an interactive device consisting of areas A and A′ of non-coated substrate contrasting with areas B, B′, B″, and B′″ of conductively coated substrate as shown in FIG. 1. However, a known disadvantage of current such designs is that the contrast between the coated and adjacent uncoated region is plainly visible in reflected light, often leading to consumer dissatisfaction. This contrast arises from the optical inhomogeneity created by the optical properties of the transparent conductive coating, (typically having a refractive index greater than 1.65), compared to the refractive index of the uncoated adjacent region, (typically having a refractive index in the range of 1.5 to 1.55). Further, in many interaction devices, a delineated transparent conductive coating is affixed on both sides of the same substrate thus even further exacerbating the consequences of the optical inhomogeneity on both sides of the substrate. This optical inhomogeneity may require the interactive input device to be configured with the information device such as a liquid crystal display in front of the interactive input device, a configuration not optimum for interactive performance for the consumer. This invention reduces the optical inhomogeneity between the areas of non-coated substrate and the areas of coated substrate. This allows for the interactive input device to be bonded directly in front of the information device, such as a liquid crystal display, the configuration preferred for electrical and optical performance by the consumer.

### SUMMARY OF THE INVENTION

The present invention contemplates the coating of a transparent metal oxide material using conventional methods known in the wet chemical coating art such as spin coating, roll coating, meniscus coating, dip coating, spray coating, or angle dependent dip coating on a discrete patterned conductively coated glass substrate as used in a transparent interactive, input device such as a transparent digitizer, or a near field imaging touch screen, or an electromagnetic touch screen, or an electrostatic touch screen. Physical vapor deposition techniques, such as coating by sputtering or coating by evaporation, are also applicable coating methods. When the additional outermost transparent layer of, for example, a metal oxide such as silicon dioxide, is disposed on the substrate on top of the outermost layer of the patterned transparent conductively coating, visible contrast between the non-conductively coated areas of the coated panel and the conductively coated areas of the coated panel is reduced and overall light transmission is increased. It is most preferred to use the wet chemical coating method known to those skilled in the art as dip coating, or angle dependent dip coating, to establish a coating simultaneously on both sides of the delineated conductively coated substrate.

In one form, the invention is a reduced contrast, increased transmission conductively coated panel comprising a substrate having a first surface and a second surface, a transparent, conductive layer on at least one surface of the substrate, the conductive layer being in a predetermined pattern such that there is at least one area having a conductive layer thereon and a second area without a conductive layer on said one substrate surface. A transparent layer of metal oxide overlies both areas of the substrate surface such that visible contrast between the areas is reduced and light transmission through the coated panel is increased and wherein the coated panel is adapted for use in an interactive device.

In other aspects, the transparent substrate may be glass or plastic, the transparent, conductive layer may be one of indium tin oxide, doped tin oxide or doped zinc oxide, while the transparent metal oxide layer may be silicon dioxide.

In yet other aspects, the second surface of the substrate may also include a transparent, conductive layer in a predetermined pattern with at least one conductively coated area and a second area without a conductive coating, and a transparent metal oxide layer, for example silicon dioxide, overlying those areas.

In yet a further aspect of the invention, a transparent interactive input device comprises an electro-optic display for displaying information when electricity is applied thereto and a conductively coated panel optically bonded to the electro-optic display. The panel includes a substrate and a transparent, conductive layer on at least one surface of the substrate, the conductive layer being in a predetermined pattern such that there is at least one area having a conductive layer thereon and a second area without a conductive layer. A transparent layer of metal oxide overlies both areas whereby visible contrast between the areas is reduced and light transmission through the coated panel is increased.

The present invention also includes a method for making an interactive information device comprising forming a reduced contrast, increased light transmitting, conductively coated panel and optically bonding the conductively coated panel to an electro-optic display for displaying information when electricity is applied thereto. The conductively coated panel is formed by providing a transparent substrate having first and second surfaces, applying a transparent conductive layer on at least one surface of the substrate in a predetermined pattern such that there is at least one area having a conductive layer thereon and a second area without a conductive layer on that one substrate surface, and applying a transparent layer of metal oxide overlying the one and second areas of that one substrate surface whereby visible contrast between the one area and second area is reduced and light transmission through the coated panel is increased.

In other aspects, the method includes applying a transparent, conductive layer on the other of the first and second surfaces of the substrate in a predetermined pattern such that there is at least one area having a conductive layer thereon and a second area without a conductive layer and applying a transparent layer of metal oxide overlying the one and second areas of the other substrate surface.

The transparent metal oxide layers may be applied by physical vapor, deposition coating such as sputtering or evaporation coating while the transparent metal oxide layer or layers may be applied by a wet chemical deposition process such as spin coating, roll coating, meniscus coating, dip coating, spray coating or angle dependent dip coating. The dip coating or angle dependent dip coating includes dip coating the substrate having the transparent, conductive layers thereon in a precursor solution for silicon dioxide such that the transparent layers of metal oxide are applied to both surfaces of the substrate simultaneously. The method also includes applying a conductive electrode pattern over each of the respective surfaces of the substrate after application of the transparent conductive layers and prior to application of the transparent metal oxide layers. The transparent conductive layers and conductive electrode patterns may be cured by baking at a predetermined temperature for a predetermined time.

The present invention therefore provides an improved conductively coated panel for use in transparent, interactive input devices which both reduces visible contrast between areas coated with conductive layers and areas not coated with conductive layers while increasing light transmission through the coated panel. The coated panels are, therefore, especially useful in interactive devices such as with electro-optic displays for displaying information when electricity is applied thereto.

These and other objects, advantages, purposes and features of the invention will become more apparent from a study of the following description taken in conjunction with the drawings.

### BRIEF DESCRIPTION OF THE DRAWINGS

FIG. 1 is a plan view of a conventional panel for an interactive device having both conductively coated and non-conductively coated areas on one surface of the substrate;

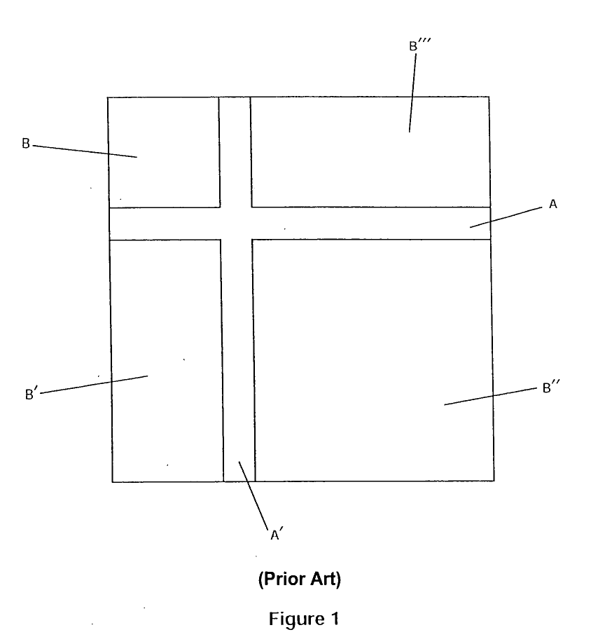

FIG. 2 is a sectional side elevation of a conductively coated panel in accordance with the present invention including a patterned, conductive thin film and an outermost film of metal oxide deposited thereover on each surface of the panel; and

FIG. 3 is a flow diagram of a preferred method of the present invention for making the conductively panel/interactive information device of FIG. 2.

### DESCRIPTION OF THE PREFERRED EMBODIMENTS

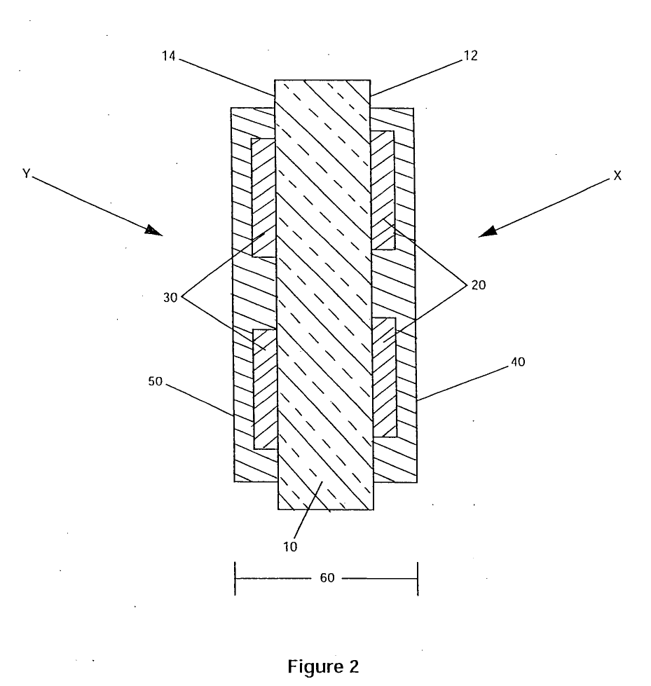

More specifically, and as shown in FIG. 2, the invention relates to an improved, reduced contrast, increased transmission conductively coated panel 60 comprising a transparent substrate 10 having a first surface 12 and a second surface 14. Substrate 10 may be transparent glass, such as soda lime glass, or, may be an optical plastic comprising a conductively coated cyclic olefin copolymer plastic substrate as disclosed in U.S. patent application Ser. No. 09/946,228, filed Sep. 5, 2001, entitled IMPROVED PLASTIC SUBSTRATE FOR INFORMATION DEVICES AND METHOD FOR MAKING SAME, the disclosure of which is hereby incorporated by reference herein in its entirety. Such rigid plastic substrate may be formed from a cyclic olefin copolymer (COC) such as is available from Ticonca of Summit, N.J., under the trade name “Topas.” Cyclic olefin-containing resins provide an improved material for a rigid, transparent conductively coated substrate suitable for use in an information display. The improved information display incorporating the improved plastic substrate is lightweight, durable, flex resistant, dimensionally stable and break resistant as compared to other, more conventional substrates.

A rigid plastic substrate can be formed by extrusion, casting or injection molding. When injection molding is used such as when forming a substrate from a cyclic olefin copolymer (COC), a non-planar curved (spherical or multiradius) part can be formed, optionally with at least one surface roughened (such as by roughening/patterning a surface of the tool cavity used for injection molding) so as to have a light-diffusing, anti-glare property.

A transparent, plastic substrate such as one formed from cyclic olefin polymer resin can be used to form a rigid panel or back plate for use in a resistive membrane touch device where the cyclic olefin panel functions as a transparent back plate for a flexible, conductive, transparent touch member assembly as is also described in U.S. patent application Ser. No. 09/946,228, filed Sep. 5, 2001, incorporated by reference above.

A transparent, conductive, patterned thin film (such as indium tin oxide or doped tin oxide, such as Sb or F doped tin oxide, or doped zinc oxide) 20 is deposited in a predetermined pattern with coated and non-coated areas on the first surface 12 of substrate 10. Preferably, a second transparent, conductive, patterned thin film 30 (such as indium tin oxide or doped tin oxide, such as Sb or F doped tin oxide, or doped zinc oxide) is also deposited on the second surface 14 of substrate 10 also in a predetermined pattern with coated and non-coated areas. A first surface outermost film 40 comprises a transparent silicon dioxide film deposited on transparent conductive patterned film 20. The preferred range of thickness of the silicon dioxide (SiO₂) film is about 600 to about 1400 Angstroms thick, most preferred about 800 to about 1200 angstroms thick. Silicon dioxide film 40 is at least about 600 Angstroms thick in those areas overlying conductive film 20. The second surface outermost film 50 also preferably comprises a transparent silicon dioxide film deposited on transparent conductive patterned film 30 and may have the same or differing thickness as film 40. Layers 40 and 50 have a refractive index at the Sodium D line of at least about 2.00 and less than about 2.2. Although metal oxides are preferred, the present invention encompasses use of non-metal oxide layers such as boron oxide or the like.

Other metal oxide materials may also be used for layers 40 and 50 including tantalum oxide, zirconium oxide, titanium dioxide, tungsten oxide, or similar transition metal and non-transition metal oxides. Such materials would be used in thicknesses within the range of about 100 to about 50,000 Angstroms. For example, for a metal oxide, layers 40, 50 preferably are at least about 500 Angstroms to about 10,000 Angstroms thick in those areas overlying conductive films 20 or 30.

Multilayer stack 20 reduces glare from light incident thereon for direction X and multilayer stack 30 reduces glare from light incident thereon for direction Y. Silicon dioxide (SiO₂) layers 40 and 50 increase visible light transmission through panel 60 (that typically comprises a transparent glass substrate) as compared to uncoated glass by at least about 1.5% T; and preferably by at least about 4% T; and most preferably by at least about 6% T.

Light transmission through improved reduced-glare conductive coated panel 60 is at least about 85% T; more preferably at least about 90% T, and most preferably at least about 95% T (transmission measured using an integrating sphere across the visible spectrum). Optical inhomogeneity is reduced between the transparent conductively coated regions and the non-coated regions rendering these delineation regions essentially visually indistinguishable by a viewer so that there is no substantial contrast apparent when viewed in reflected light.

In some forms of the invention, it may be useful to incorporate a reduced glare, conductively coated panel having increased visible light transmission and suitable for use as a touch screen, digitizer panel or substrate in an information display and incorporating one or more thin film interference layers forming a thin film stack on opposite surfaces of a substrate such as that described herein and a transparent electrically conductive coating on the outer most layer of one or both of the thin film stacks, such as described in U.S. patent application Ser. No. 09/883,654, filed Jun. 18, 2001, now U.S. Pat. No. 6,878,240, issued Sep. 7, 2004, entitled ENHANCED LIGHT TRANSMISSION CONDUCTIVE COATED TRANSPARENT SUBSTRATE AND METHOD FOR MAKING SAME, the disclosure of which is hereby incorporated by reference herein.

In some forms of the present invention, it may also be useful to incorporate a flexible, transparent, conductively coated layer with a rigid, transparent, conductively coated substrate such as that described herein to form an interactive information device and to include spacer members or dots as described in U.S. patent application Ser. No. 09/954,139, filed Sep. 17, 2001, now U.S. Pat. No. 6,627,918, issued Sep. 30, 2003, entitled SPACER ELEMENTS FOR INTERACTIVE INFORMATION DEVICES AND METHOD FOR MAKING SAME, the disclosure of which is incorporated by reference herein as set forth above. Such an assembly includes an improved process and materials for producing uniformly dispersed, consistent, durable, essentially non-visible, fixed substrate-interpane-spacer elements (for example “spacer dots”) for spacing opposing conductive surfaces of the flexible top sheet and rigid bottom sheet or substrate of such an interactive information device.

Preferably, at least layers 40 and 50 are deposited by wet chemical deposition (such as disclosed in U.S. Pat. No. 5,725,957, Varaprasad et al. etc or such as disclosed by U.S. Pat. Nos. 5,900,275; 5,838,483; 5,604,626; 5,525,264; and 5,277,986 all commonly assigned to Donnelly Corporation of Holland, Mich., which are all incorporated by reference herein in their entireties). For example, a preferred precursor solution comprises about 18.75% tetraethylorthosilicate, about 2.23% acetic anhydride, about 3.63% water, about 0.079% phosphoric acid (85% acid in aqueous solution), about 0.91% 2,4-pentanedione, about 1.24% 1-pentanol, about 19.38% ethyl acetate, about 15% ethanol, about 17.5% methanol and about 21.25% acetone (all component concentrations are expressed as weight percentages of the total weight of the solution). This equates to a concentration of tetraethylorthosilicate precursor, expressed as equivalents of silica, of about 5.4%.

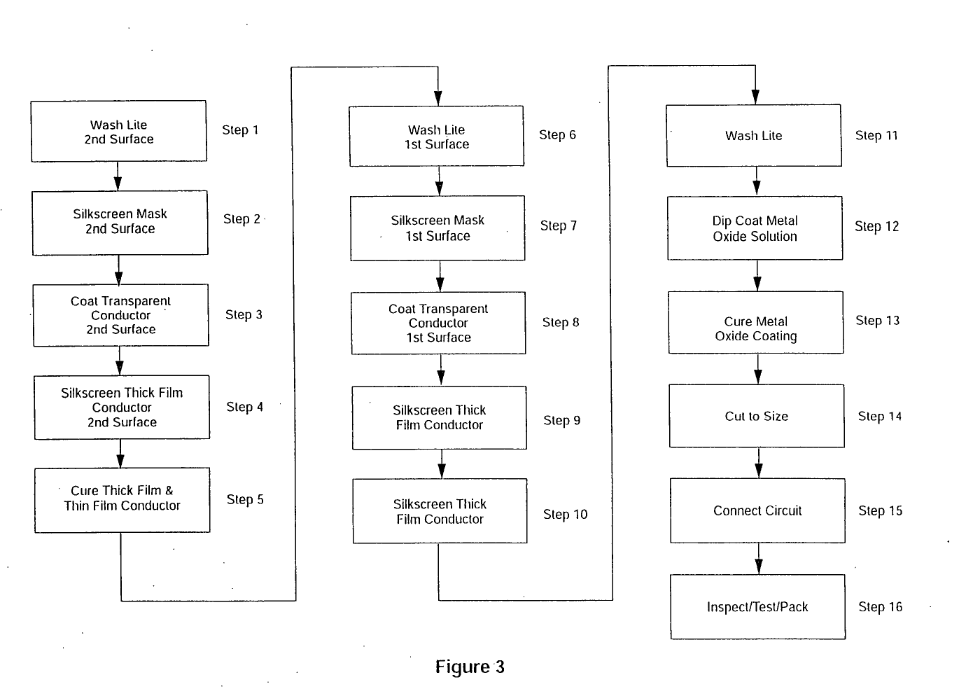

The preferred process, and as shown in FIG. 3, for the manufacture of digitizer panels starts with using conventional glass cleaning techniques for the preparation of the raw glass lite that typically is provided as a sheet or panel of dimension typically four (4) inches diagonal or greater. Lites can be processed in the bent or flat product configuration, and lites can be processed in the final product size, or in what is known as the stocksheet configuration allowing for the subsequent cutting from and manufacture of multiple touch devices from one lite. Prior to the deposition of the transparent conductive thin film on the second surface, a pattern of mask material is applied to the raw glass using a silk screen coating method, 325-mesh stainless steel screen. This allows for the removal of the thin film conductor, indium tin oxide for example, following the deposition of the conductive thin film. The conductive thin film could also be removed in the required configuration using a post deletion method such as by laser ablation or post chemical etching with photolithography. The conductive thin film, preferably indium tin oxide, is then deposited on the second surface of the lite, preferably by the sputtering physical vapor deposition technique or evaporation physical vapor deposition technique. A thick film conductive electrode pattern, typically a silver glass frit such as Dupont 7713, is then applied using a silk screen coating method, 325 stainless steel mesh silk screen with glass frit as required based on the digitizer design. The thin film conductor and the thick film conductor are then cured using a conventional baking process, such as 480 degrees C. for 60 minutes. The thin film conductor may be chemically reduced in an inert forming gas curing environment. The substrate is then washed using conventional glass washing procedures. Prior to the deposition of the transparent conductive thin film on the first surface, a pattern of a mask material is applied to the raw glass using a silk screen coating method, 325-mesh stainless steel screen. This allows removal of the thin film conductor, indium tin oxide for example, following the deposition of the conductive film. The conductive thin film could also be removed in the required configuration using a post deletion method such as by laser ablation or chemical etching such as with photolithography or with a screened chemical etch paste (typically an acid based paste). The conductive thin film, indium tin oxide, is then deposited on the first surface of the lite, preferably by the sputtering physical vapor deposition technique or evaporation physical vapor deposition technique. A thick film conductive electrode pattern, typically a silver glass frit such as Dupont 7713, is then applied using a silk screen coating method, 325 stainless steel mesh silk screen with glass frit as required based on the digitizer design. The thin film conductor and the thick film conductor are then cured using a conventional baking process, such as 480 degrees C. for 60 minutes, followed by a chemical reduction in an inert forming gas at 290 degrees C. for 30 minutes. The double sided conductively coated substrate is then washed using conventional glass washing techniques. Both the first and second surfaces are then coated with a silicon dioxide thin film using a dip coating technique. The double-sided silicon dioxide film is then cured using a conventional baking process, such as 480 degrees C. for 60 minutes. The thin film conductor under the silicon dioxide may be chemically reduced in an inert forming gas curing environment. The lites are then cut to final digitizer dimensions using conventional glass cutting techniques. A flexible electric connector is electrically connected to the complete assembly for attachment to the information device. This device may be optically bonded to the first surface of a liquid crystal display. The resulting product is the complete transparent digitizer interactive device.

While several forms of the invention have been shown and described, other forms will now be apparent to those skilled in the art. Therefore, it will be understood that the embodiments shown in the drawings and described above are merely for illustrative purposes, and are not intended to limit the scope of the invention which is defined by the claims which follow.

The embodiment of the invention in which an exclusive property or privilege is claimed are as follows:

1. A method for making an interactive information device comprising:
forming a reduced contrast, increased light transmitting, conductively coated panel by providing a transparent substrate having first and second surfaces, applying a transparent, conductive layer on at least one surface of said first and second surfaces of said substrate in a predetermined pattern such that there is at least one area having a conductive layer thereon and an adjacent second area without a conductive layer on said one substrate surface, and applying a transparent layer of metal oxide commonly overlying both said one and said second areas of said one substrate surface including selecting said metal oxide layer to have a refractive index at the sodium D line and a thickness that, in combination, reduce optical contrast between said one area and said second area such that visible contrast between said one area and said second area is reduced and light transmission through said coated panel is increased by said layer of metal oxide that commonly overlies both said one and said second areas;
applying a transparent, conductive layer on the other of said first and second surfaces of said substrate in a predetermined pattern such that there is at least one area having a conductive layer thereon and a second area without a conductive layer on said other substrate surface and applying a transparent layer of metal oxide overlying said one and said second areas of said other substrate surface;
applying each of said transparent layers of metal oxide by a wet chemical deposition process; and
attaching said conductively coated panel to an electro-optic display for displaying information when electricity is applied thereto.

2. The method of claim 1 wherein said wet chemical deposition process is selected from the group consisting of spin coating, roll coating, meniscus coating, dip coating, spray coating and angle dependent dip coating.

3. The method of claim 1 wherein said wet chemical deposition process includes forming a coated substrate by dip coating said substrate having said transparent, conductive layers thereon in a precursor solution for a metal oxide such that said transparent layers of metal oxide are applied to both surfaces of said substrate simultaneously.

4. The method of claim 3 including curing said coated substrate by baking at a predetermined temperature for a predetermined time.

5. The method of claim 4 including chemically reducing said transparent conductive layers in an inert forming gas curing environment.

6. The method of claim 1 wherein each of said transparent, conductive layers on said substrate surfaces is applied in a predetermined pattern by depositing said conductive layers over each of said substrate surfaces and removing said conductive layers in said second area on each substrate surface by a post deletion method.

7. The method of claim 6 wherein said post deletion method is selected from the group consisting of laser ablation and chemical etching.

8. A method for making an interactive information device comprising:
forming a reduced contrast, increased light transmitting, conductively coated panel by providing a transparent substrate having first and second surfaces, applying a transparent, conductive layer on at least one surface of said first and second surfaces of said substrate in a predetermined pattern such that there is at least one area having a conductive layer thereon and an adjacent second area without a conductive layer on said one substrate surface, and applying a transparent layer of metal oxide commonly overlying both said one and said second areas of said one substrate surface including selecting said metal oxide layer to have a refractive index at the sodium D line and a thickness that, in combination, reduce optical contrast between said one area and said second area such that visible contrast between said one area and said second area is reduced and light transmission through said coated panel is increased by said layer of metal oxide that commonly overlies both said one and said second areas;
applying said transparent layer of metal oxide by a wet chemical deposition process;
attaching said conductively coated panel to an electro-optic display for displaying information when electricity is applied thereto.

9. The method of claim 8 wherein said wet chemical deposition process is selected from the group consisting of spin coating, roll coating, meniscus coating, dip coating, spray coating and angle dependent dip coating.

10. The method of claim 8 wherein said wet chemical deposition process includes forming a coated substrate by dip coating said substrate having said transparent, conductive layer thereon in a precursor solution for silicon dioxide.

11. The method of claim 10 including curing said coated substrate by baking at a predetermined temperature for a predetermined time.

12. The method of claim 11 including chemically reducing said transparent conductive layer in an inert forming gas curing environment.

13. A method for making an interactive information device comprising:
forming a reduced contrast, increased light transmitting, conductively coated panel by providing a transparent substrate having first and second surfaces, applying a transparent, conductive layer on at least one surface of said first and second surfaces of said substrate in a predetermined pattern such that there is at least one area having a conductive layer thereon and an adjacent second area without a conductive layer on said one substrate surface, and applying a transparent layer of metal oxide commonly overlying both said one and said second areas of said one substrate surface including selecting said metal oxide layer to have a refractive index at the sodium D line and a thickness that, in combination, reduce optical contrast between said one area and said second area such that visible contrast between said one area and said second area is reduced and light transmission through said coated panel is increased by said layer of metal oxide that commonly overlies both said one and said second areas;
applying said transparent, conductive layer in a predetermined pattern by depositing said conductive layer over said substrate surface and selectively removing said conductive layer in said second area by a post deletion method;
attaching said conductively coated panel to an electro-optic display for displaying information when electricity is applied thereto.

14. The method of claim 13 wherein said post deletion method is selected from the group consisting of laser ablation and chemical etching.

15. The interactive information display device produced by the method comprising:
forming a reduced contrast, increased light transmitting, conductively coated panel by providing a transparent substrate having first and second surfaces, applying a transparent, conductive layer on at least one surface of said first and second surfaces of said substrate in a predetermined pattern such that there is at least one area having a conductive layer thereon and an adjacent second area without a conductive layer on said one substrate surface, and applying a transparent layer of metal oxide commonly overlying both said one and said second areas of said one substrate surface including selecting said metal oxide layer to have a refractive index at the sodium D line and a thickness that, in combination, reduce optical contrast between said one area and said second area such that visible contrast between said one area and said second area is reduced and light transmission through said coated panel is increased by said layer of metal oxide that commonly overlies both said one and said second areas;
attaching said conductively coated panel to an electro-optic display for displaying information when electricity is applied thereto.

16. The interactive information display device produced by the method of claim 15 wherein said electro-optic display comprises a liquid crystal display.

17. The interactive information display device produced by the method of claim 16 wherein said interactive information display device comprises a touch interactive information display device.

18. The interactive information display device produced by the method comprising:
forming a reduced contrast, increased light transmitting, conductively coated panel by providing a transparent substrate having first and second surfaces, applying a transparent, conductive layer on at least one surface of said first and second surfaces of said substrate in a predetermined pattern such that there is at least one area having a conductive layer thereon and an adjacent second area without a conductive layer on said one substrate surface, and applying a transparent layer of metal oxide commonly overlying both said one and said second areas of said one substrate surface including selecting said metal oxide layer to have a refractive index at the sodium D line and a thickness within the range of about 100 Angstroms to about 50,000 Angstroms, said refractive index at the sodium D line and said thickness of said metal oxide layer, in combination, reducing optical contrast between said one area and said second area such that visible contrast between said one area and said second area is reduced and light transmission through said coated panel is increased by said layer of metal oxide that commonly overlies both said one and said second areas;
said transparent, conductive layer being applied in a predetermined pattern by one of:
a) applying a pattern of mask material to said substrate surface to mask said second area, depositing said conductive layer over said surface including over said pattern of mask material, and removing said pattern of mask material and conductive layer thereon to form said one area and said second area on said surface, and
b) depositing said conductive layer over said substrate surface and selectively removing said conductive layer in said second area by a post deletion method;
said metal oxide layer comprising at least one selected from the group consisting of silicon dioxide, tantalum oxide, zirconium oxide, titanium dioxide and tungsten oxide; and
attaching said conductively coated panel to an electro-optic display for displaying information when electricity is applied thereto.

19. The interactive information display device produced by the method of claim 18 wherein said electro-optic display comprises a liquid crystal display.

20. The interactive information display device produced by the method of claim 19 wherein said interactive information display device comprises a touch interactive information display device.

21. A method for making an interactive information device comprising:
forming a reduced contrast, increased light transmitting, conductively coated panel by providing a transparent substrate having first and second surfaces;
applying a transparent, conductive layer on said first surface of said substrate in a predetermined pattern such that there is at least one area having a conductive layer thereon and an adjacent second area without a conductive layer on said first substrate surface, and applying a transparent layer of metal oxide commonly overlying both said one and said second areas of said first substrate surface including selecting said metal oxide layer to have a refractive index at the sodium D line and a thickness within the range of about 100 Angstroms to about 50,000 Angstroms, said refractive index at the sodium D line and said thickness of said metal oxide layer, in combination, reducing optical contrast between said one area and said second area such that visible contrast between said one area and said second area is reduced and light transmission through said coated panel is increased by said layer of metal oxide that commonly overlies both said one and said second areas of said first substrate surface;
depositing said conductive layer over said first substrate surface and selectively removing said conductive layer in said second area of said first substrate surface by a post deletion method;
applying a transparent, conductive layer on said second surface of said substrate in a predetermined pattern such that there is at least one area having a conductive layer thereon and an adjacent second area without a conductive layer on said second substrate surface, and applying a transparent layer of metal oxide commonly overlying both said one and said second areas of said second substrate surface including selecting said metal oxide layer that is applied to said second substrate surface to have a refractive index at the sodium D line and a thickness within the range of about 100 Angstroms to about 50,000 Angstroms, said refractive index at the sodium D line and said thickness of said metal oxide layer applied to said second substrate surface, in combination, reducing optical contrast between said one area and said second area on said second substrate surface such that visible contrast between said one area and said second area on said second substrate surface is reduced and light transmission through said coated panel is increased by said layer of metal oxide that commonly overlies both said one and said second areas of said second substrate surface; and
attaching said conductively coated panel to an electro-optic display for displaying information when electricity is applied thereto.

22. The method of claim 21 wherein said post deletion method comprises photolithography.

23. The method of claim 22 wherein said post deletion method comprises chemical etching.

24. The method of claim 21 including depositing said conductive layer over said second substrate surface and selectively removing said conductive layer in said second area of said second substrate surface by a post deletion method.

25. The method of claim 24 wherein said post deletion method comprises photolithography.

26. The method of claim 25 wherein said post deletion method comprises chemical etching.

27. The interactive information display device produced by the method of claim 26.

28. The interactive information display device produced by the method of claim 27 wherein said electro-optic display comprises a liquid crystal display.

29. The interactive information display device produced by the method of claim 27 wherein said interactive information display device comprises a touch interactive information display device.

30. A method for making an interactive information device comprising:
forming a reduced contrast, increased light transmitting, conductively coated panel by providing a transparent substrate having first and second surfaces;
applying a transparent, conductive layer comprising indium tin oxide on said first surface of said substrate in a predetermined pattern such that there is at least one area having a conductive layer thereon and an adjacent second area without a conductive layer on said first substrate surface, and applying a transparent layer of metal oxide comprising silicon dioxide commonly overlying both said one and said second areas of said first substrate surface including selecting said metal oxide layer to have a refractive index at the sodium D line and a thickness within the range of about 100 Angstroms to about 50,000 Angstroms, said refractive index at the sodium D line and said thickness of said metal oxide layer, in combination, reducing optical contrast between said one area and said second area such that visible contrast between said one area and said second area is reduced and light transmission through said coated panel is increased by said layer of metal oxide that commonly overlies both said one and said second areas of said first substrate surface;
applying a transparent, conductive layer comprising indium tin oxide on said second surface of said substrate in a predetermined pattern such that there is at least one area having a conductive layer thereon and an adjacent second area without a conductive layer on said second substrate surface, and applying a transparent layer of metal oxide comprising silicon oxide commonly overlying both said one and said second areas of said second substrate surface including selecting said metal oxide layer that is applied to said second substrate surface to have a refractive index at the sodium D line and a thickness within the range of about 100 Angstroms to about 50,000 Angstroms, said refractive index at the sodium D line and said thickness of said metal oxide layer applied to said second substrate surface, in combination, reducing optical contrast between said one area and said second area on said second substrate surface such that visible contrast between said one area and said second area on said second substrate surface is reduced and light transmission through said coated panel is increased by said layer of metal oxide that commonly overlies both said one and said second areas of said second substrate surface;
said applying said transparent, conductive layer on said first substrate surface including depositing said conductive layer over said first substrate surface and selectively removing said transparent, conductive layer in said second area of said first substrate surface by a post deletion method wherein said post deletion method comprises photolithography and chemical etching, and including depositing said conductive layer over said second substrate surface and selectively removing said conductive layer in said second area of said second substrate surface by a post deletion method wherein said post deletion method comprises photolithography and chemical etching; and
attaching said conductively coated panel to an electro-optic display for displaying information when electricity is applied thereto.

31. The method of claim 30 including applying said metal oxide layer commonly overlying both said one and said second areas of said first substrate surface with a thickness in the range from about 100 angstroms to about 1,400 angstroms and applying said metal oxide layer commonly overlying both said one and said second areas of said second substrate surface with a thickness in the range from about 100 angstroms to about 1,400 angstroms.

32. The method of claim 31 including applying said transparent layer of metal oxide on said first substrate surface by physical vapor deposition sputter coating and including applying said transparent layer of metal oxide on said second substrate surface by physical vapor deposition sputter coating.

33. The method of claim 32 including applying said transparent, conductive layer on said first substrate surface by physical vapor deposition sputter coating and including applying said transparent, conductive layer on said second substrate surface by physical vapor deposition sputter coating.

34. The method of claim 31 including applying said metal oxide layer commonly overlying both said one and said second areas of said first substrate surface with a thickness in the range from about 100 angstroms to about 600 angstroms and applying said metal oxide layer commonly overlying both said one and said second areas of said second substrate surface with a thickness in the range from about 100 angstroms to about 600 angstroms.

35. The interactive information display device produced by the method of claim 34.

36. The interactive information display device produced by the method of claim 34 wherein said electro-optic display comprises a liquid crystal display.

37. The interactive information display device produced by the method of claim 36 wherein said interactive information display device comprises a touch interactive information display device.

38. The method of claim 34 including applying said metal oxide layer commonly overlying both said one and said second areas of said first substrate surface with a thickness of about 500 angstroms and applying said metal oxide layer commonly overlying both said one and said second areas of said second substrate surface with a thickness of about 500 angstroms.
